(19) United States
(12) Patent Application Publication
(10) Pub. No.: US 2005/0248002 A1
(43) Pub. Date: Nov. 10, 2005

(54) Fill for large volume vias

(76) Inventors: Michael Newman, Gilbert, AZ (US); Michael Stora, Maricopa, AZ (US); Cynthia Polsky, Chandler, AZ (US)

Correspondence Address: Michael A. Bernadicou;BLAKELY, SOKOLOFF, TAYLOR & ZAFMAN LLP, Seventh Floor, 12400 Wilshire Boulevard, Los Angeles, CA, 90025, US

(21) Appl. No.: 10/841,136

(22) Filed: May 7, 2004

(51) Int. Cl. H01L 29/40; H01L 21/44

(52) U.S. Cl. 257/621; 438/675; 438/667; 257/774

(57) ABSTRACT

The invention provides a high aspect ratio via. A dielectric plug may fill a volume within a conformal conductive layer.

### BACKGROUND

Background of the Invention

In a microelectronic structure, a conductive via may be used to transfer signals through a layer of material. In some applications, such as vias through silicon interposers, vias in micro electromechanical systems (“MEMS”), vias through a wafer from an active front side to a back side, and vias in other applications, the vias may have a high aspect ratio, where the depth of the via may be twice as great as the width, or even greater.

### BRIEF DESCRIPTION OF THE DRAWINGS

FIG. 1 is a cross sectional side view of a microelectronic structure according to one embodiment of the present invention.

FIG. 2 is a cross sectional side view that illustrates the via layer and substrate before creation of the via well.

FIG. 3 is a cross sectional side view that illustrates the via layer and substrate after the via layer has been patterned to form the via well.

FIGS. 3a and 3b are top views that illustrate embodiments of the via well.

FIG. 4 is a cross sectional side view that illustrates the via layer and substrate after an insulating layer has been formed.

FIG. 5 is a cross sectional side view that illustrates a barrier layer that may be deposited in the via well.

FIG. 6 is a cross sectional side view that illustrates a mask that may be deposited on the via layer or other layers.

FIG. 7 is a cross sectional side view that illustrates a conductive layer that may be deposited on the barrier layer.

FIG. 8 is a cross sectional side view that illustrates a barrier layer that may be deposited on the conductive layer.

FIG. 9 is a cross sectional side view that illustrates a plug material that may fill volume at the center of the via.

FIG. 10 is a cross sectional side view that illustrates one embodiment of the via after excess material has been removed.

FIG. 11 is a cross sectional side view that illustrates a bulk metal layer that may be deposited on the via and via layer.

FIG. 12 is a cross sectional side view that illustrates a top connective structure that may be on the bulk metal layer.

FIG. 13 is a cross sectional side view that illustrates an alternate embodiment in which there is no substrate.

FIG. 14 is a cross sectional side view that illustrates a device that may comprise the via.

FIG. 15 is a cross sectional side view that illustrates another device that may comprise the via.

### DETAILED DESCRIPTION

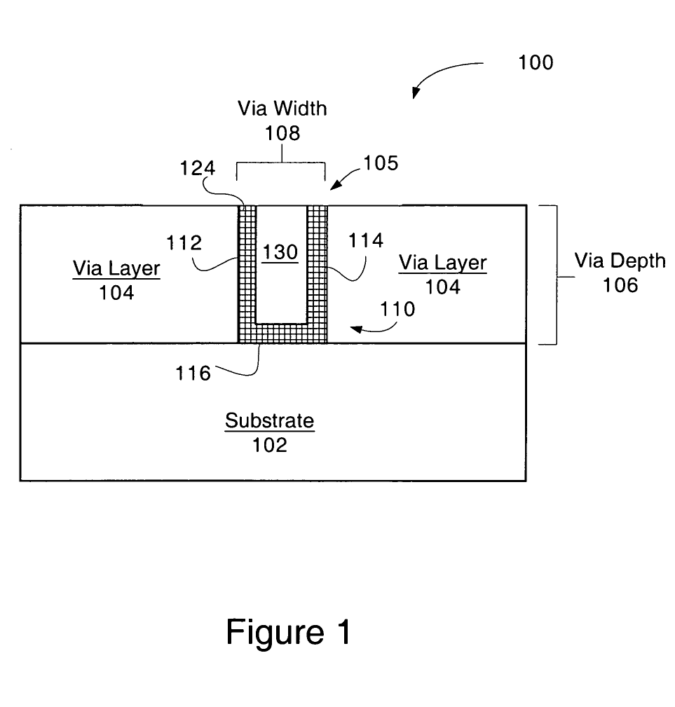

FIG. 1 is a cross sectional side view of a microelectronic structure 100 according to one embodiment of the present invention. The microelectronic structure 100 may include a substrate 102 in one embodiment. The substrate 102 may be a piece of material, such as a piece of silicon or other material. The substrate 102 may be any surface generated, and may comprise, for example, active and passive devices that are formed on a silicon wafer, such as transistors, capacitors, resistors, local interconnects, and others. The substrate 102 may be a physical structure, a layer that is a basic workpiece transformed and/or added to by various processes into the desired microelectronic configuration, or another material or materials. The substrate 102 may include conducting material, insulating material, semiconducting material, and other materials or material combinations. In some embodiments, the substrate 102 may be a layered structure.

The structure 100 may include a via layer 104. This via layer 104 may comprise a layer of different material or materials than the substrate 102 in some embodiments. In other embodiments, the via layer 104 may not be a separate material or layer than the substrate 102, but instead may be a different section of the same piece of material as the substrate 102.

There may be a via well 110 through the via layer 104. The via well 110 may be defined by one or more side walls 112, 114 of the via layer 104. The via well 110 may be further defined by a bottom 116. In some embodiments, the via well 110 may extend through the via layer 104 to the substrate 102, and the via bottom 116 may be a top surface of the substrate 102. In other embodiments, the structure 100 may lack a substrate 102; the via well 110 may extend all the way from top to bottom of the via layer 104, which may be from top to bottom of the structure 100, be defined by the one or more side walls 112, 114 of the via layer 104.

The via well 110 may be partially or completely filled by a via 105. In some embodiments, the via 105 may include multiple layers, which may include a conductive layer 124 to transmit signals and an inner plug 130 to fill space at the center of the via 105, and/or at the interior of the conductive layer 124. The conductive layer 124 may comprise copper, a copper alloy, or another material. The conductive layer 124 may have an exterior closer to the side walls 112, 114, and an interior closer to a center of the via well 110 (or further from the side walls 112, 114). The interior of the conductive layer 124 may encompass a center volume, which may be partially or substantially completely filled by the inner plug 130. The inner plug 130 may comprise a dielectric material or another material. The via 105 may also include additional layers. The via 105 may have a depth 106 and a width 108.

The via 105 may have a high aspect ratio. The depth 106 may be at least twice as great as the width 108 in some embodiments. In other embodiments, the depth 106 may be at least three times as great as the width 108. In yet other embodiments, the aspect ratio may be even greater, such as a 10:1 or greater aspect ratio, where the depth 106 is at least ten times as great as the width 108. In some embodiments, the via depth 106 may be in a range from about 50 microns to about 250 microns. Since the aspect ratio of the via 105 may be high, this may mean that for a via 105 with a one-hundred micron depth 106, the width 108 may be about fifty microns or less, about thirty-three microns or less, about ten microns or less, or even smaller. In other embodiments, the via 105 may have a depth 106 in a range from about 100 microns to about 800 microns. Other depths 106 may also be possible in other embodiments.

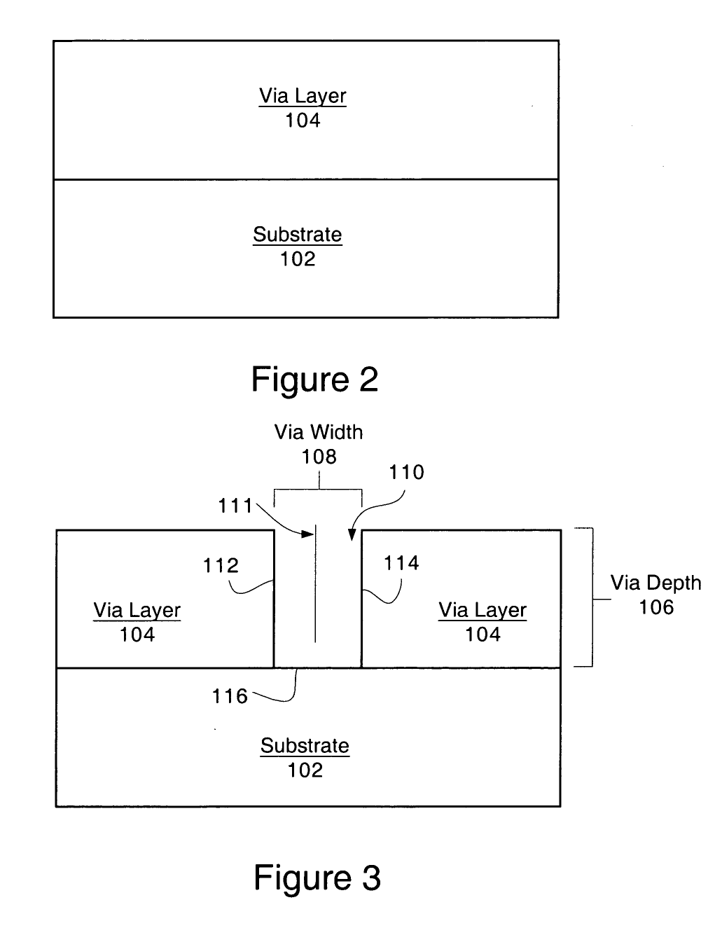

FIGS. 2 through 13 are cross sectional side views that illustrate how the microelectronic structure 100 of FIG. 1 may be fabricated in some embodiments. In other embodiments, the structure 100 may be fabricated differently. For example, some steps and layers may be omitted. Additional layers and steps may be included. Different processes may be performed, or the same and/or different processes and/or steps may be performed in a different order.

FIG. 2 is a cross sectional side view that illustrates the via layer 104 and substrate 102 before creation of the via well 110. As described above, the substrate 102 and via layer 104 may comprise two different pieces of material. Alternatively, the substrate 102 and via layer 104 may simply be two different volumes of the same piece of material, in which case the separation of the piece of material into separate substrate 102 and via layer 104 sections is merely a conceptual aid. The substrate 102 may be considered to simply be an area of the via layer 104 in embodiments such as that, or in other embodiments. Thus, the via layer 104 may include the substrate 102, with the substrate 102 simply an area of the via layer 104, or the substrate may be a different thing than the via layer 104.

The substrate 102 and/or the via layer 104 may include one or multiple different material types, and may include active and/or passive electronic devices. For example, on a bottom surface of the substrate 102 there may be active and/or passive devices which may be electrically connected to a top surface of the via layer 104 by the via 105. The active and/or passive devices may comprise multiple different materials, and the rest of the substrate 102 and via layer 104 may comprise a single piece of material, such as a single piece of silicon. Alternatively, the rest of the substrate 102 and via layer 104 may comprise multiple materials, or be different physical layers of the same or different materials.

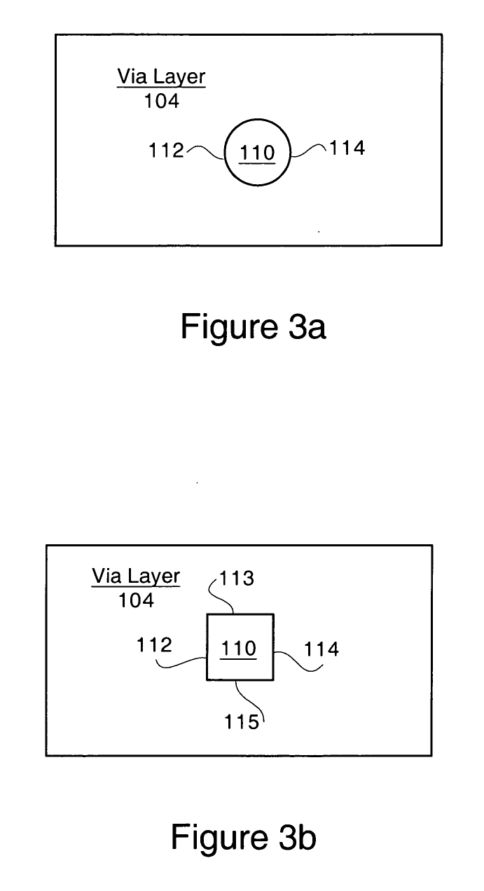

FIG. 3 is a cross sectional side view that illustrates the via layer 104 and substrate 102 after the via layer 104 has been patterned to form the via well 110, according to one embodiment. The via well 110 may be defined by side walls 112, 114 of the via layer and by a bottom 116. As discussed above, in some embodiments the bottom 116 may be at the bottom of the via layer 104, which may be a portion of the same piece of material as the substrate 102 or a different piece of material. Alternatively, the bottom 116 may be above the bottom of the via layer 104. In other embodiments, there may be no substrate 102, and the via well 110 may extend all the way through the via layer 104 and not be defined by a bottom 116. In some embodiments, the via well 110 may have a width and depth, which may be the same as the width and depth 106 of the via 105. The width and depth of the via well 110 may have a high aspect ratio, as described above. Also described above are some sizes that the width 108 and depth 106 may have.

The via well 110 may have a center, which may be a line 111 between the side walls 112, 114. A volume at or near the center line 111 of FIG. 3 may also be considered the center of the via well 110 and the via 105. Additionally, what is considered the “center” of the via 105 or via well 110 does not extend all the way to the bottom 116 of the via well 110, in embodiments where there is a bottom 116. Rather, in such embodiments the center of the via 110 is a distance away from the bottom 116, this distance being at least as great as the thickness of the conductive layer 124 on the bottom 116.

FIG. 3a is a top view that illustrates the via well 110 according to one embodiment of the present invention. In the embodiment of FIG. 3a, the via well 110 has a substantially circular cross section. The opposing sides 112, 114 that at least partially define the via well 110 are actually different portion of the single, tube-shaped side wall of the via 105. The via width 108 in this embodiment is the widest distance between two opposing sides 112, 114 of the circular via 105, which may be the diameter of the substantially circular via well 110. The center 111 (not shown) in this embodiment would be a line in the center of the circular via well 110 that is normal to the plane of the page.

FIG. 3b is a top view that illustrates the via well 110 according to another embodiment of the present invention. In the embodiment of FIG. 3b, the via well 110 has a substantially rectangular or square cross section. Opposing side walls 112, 114 of the via layer 104 at least partially define the side walls of the via well 110. In this embodiment, an additional set of opposing side walls 113, 115 of the via layer 104 further define the side walls of the via well 110. The via width 108 in this embodiment may be the largest distance between the opposing side walls 112 and 114, or the largest distance between the opposing side walls 113, 115. The center 111 (not shown) in this embodiment would be a line in the center of the square/rectangular via well 110 that is normal to the plane of the page.

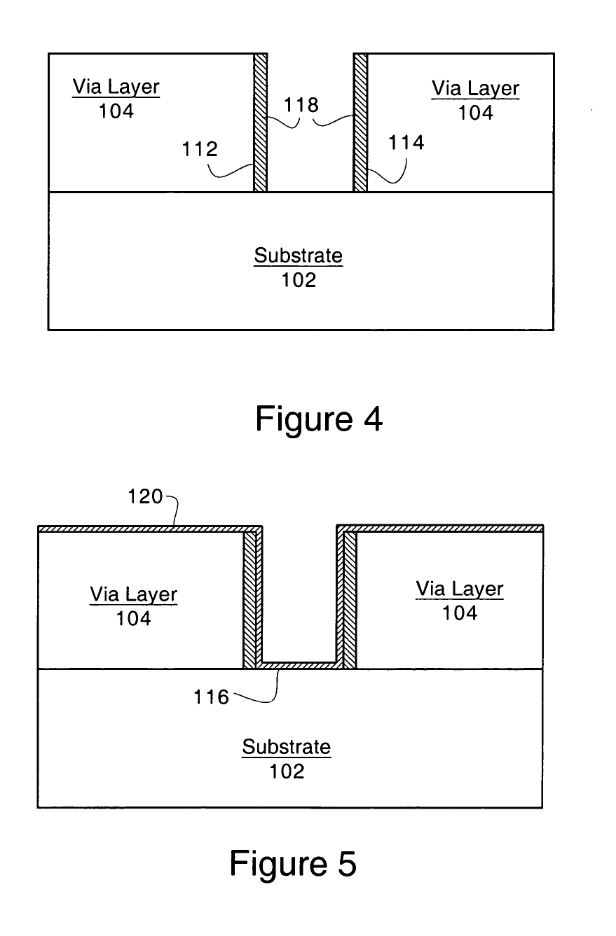

FIG. 4 is a cross sectional side view that illustrates the via layer 104 and substrate 102 after an insulating layer 118 has been formed on the side walls 112, 114 of the via well 110. Some embodiments may lack the insulating layer 118. For example, in an embodiment where the via layer 104 comprises an insulating material an insulating layer 118 may be omitted, while in an embodiment where the via layer 104 comprises a conductive material such as silicon the insulating layer 118 may be used. In an embodiment, the insulating layer 118 may comprise an insulating material such as SiO₂ or another material. This insulating layer 118 may be deposited by a method such as chemical vapor deposition (“CVD”) or another method. In some embodiments, the insulating layer 118 may initially cover the bottom 116 of the via well 110 as well as the sides, but then be etched or otherwise removed from the bottom 116 of the via well 110. In some embodiments, the insulating layer 118 may be initially formed to cover the sides of the via well 110 but not the bottom 116.

FIG. 5 is a cross sectional side view that illustrates a barrier layer 120 that may be deposited in the via well 110. The barrier layer 120 may be a thin layer of material that may prevent the conductive material that is added later from diffusing into the insulating layer 118, the via layer 104, or the substrate 102. The barrier layer 120 may prevent electromigration of the conductive material added to the via 105 during a later process. In some embodiments, the barrier layer 120 may act as an adhesion layer in addition to, or in place of, acting as a barrier layer. The barrier layer 120 may allow the conductive material to adhere to the insulating layer 118, the via layer 104, and/or the substrate 102. In one embodiment, the barrier layer 120 may comprise TaN₂. In some embodiments, the barrier layer 120 may comprise one or more of Ta, TaₓN_{y}, SiₓO_{y}, SiₓO_{y}N_{z}, or another material. In some embodiments, the barrier layer 120 may have a thickness of about 1200 angstroms where it is deposited on the top surface of the via layer 104 and near the top surface of the via layer 104 where the barrier layer 120 is deposited inside the via well 110. The barrier layer 120 thickness may decrease further into the via well 110, toward the bottom 116.

A thin seed layer of conductive material may also be formed in addition to the barrier layer 120 or in place of the barrier layer 120. In an embodiment, a seed layer of copper may be conformally sputtered onto the sides 112, 114 and bottom 116 of the via well 110 or onto the barrier layer 120. The seed layer may also be sputtered onto the top surface of the via layer 104. Thus, the barrier layer 120 illustrated in FIG. 5 may also represent a seed layer on the barrier layer 120, although for simplicity two separate barrier and seed layers are not shown. In an embodiment, this seed layer may have a thickness of 11,000 angstroms at the top of the via layer 105 and near the top of the via well 110, with the thickness decreasing further down the sides of the via well 110 toward the bottom 116. In other embodiments, the seed layer may be thinner, depending on the aspect ratio of the via 105 and the smoothness of the walls. For example, for a via 105 with a relatively small aspect ratio and smooth walls, the seed layer may have a thickness of about 500 angstroms.

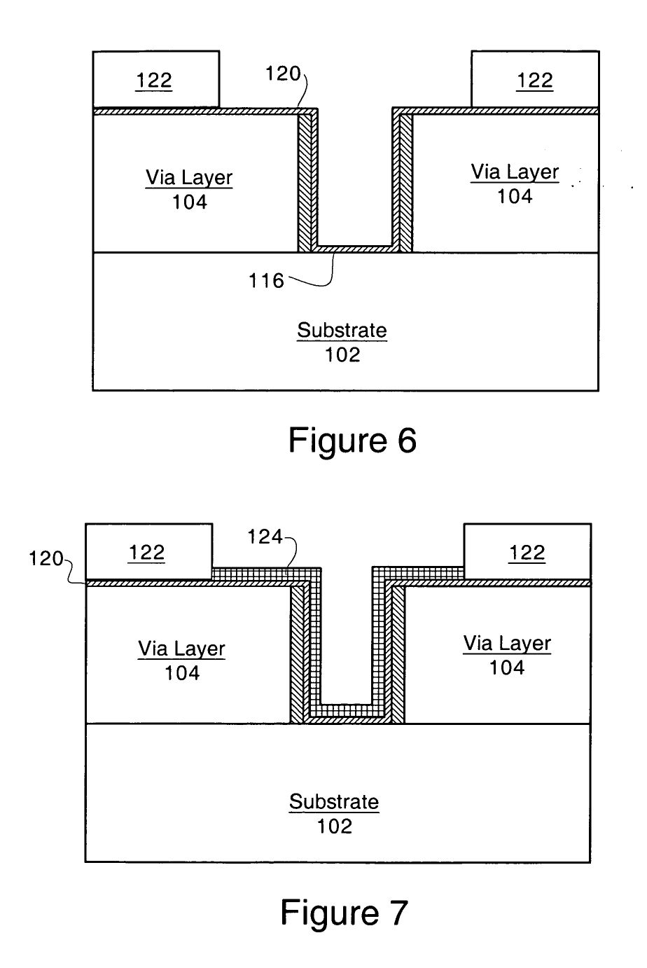

FIG. 6 is a cross sectional side view that illustrates a mask 122 that may be deposited on the via layer 104 or other layers. In some embodiments, the mask 122 may comprise a polymer-based photoresist or other material, and have a thickness in a range from about 5 microns to about 70 microns, although other thicknesses may be used. The mask 122 may be used to help define a trench, bump, pad or another connective structure. In some embodiments, the mask 122 may be formed at earlier or later stages of formation of the via 105.

FIG. 7 is a cross sectional side view that illustrates a conductive layer 124 that may be deposited on the seed layer. The conductive layer 124 may comprise copper or another conductive material. The conductive layer 124 may comprise more than one physical layer. The conductive layer 124 may comprise a bulk layer of copper conformally electroplated onto the seed layer. In an embodiment, this bulk layer may be approximately twenty microns thick. The bulk copper layer may have a thickness in a range between fifteen microns and about twenty microns in an embodiment. The bulk copper layer may have a thickness in a range between two microns and about twenty microns in another embodiment. The mask 122 may define where the bulk copper layer is electroplated by masking areas of the seed layer on which conductive material is not to be added and preventing electroplating to occur in the masked areas.

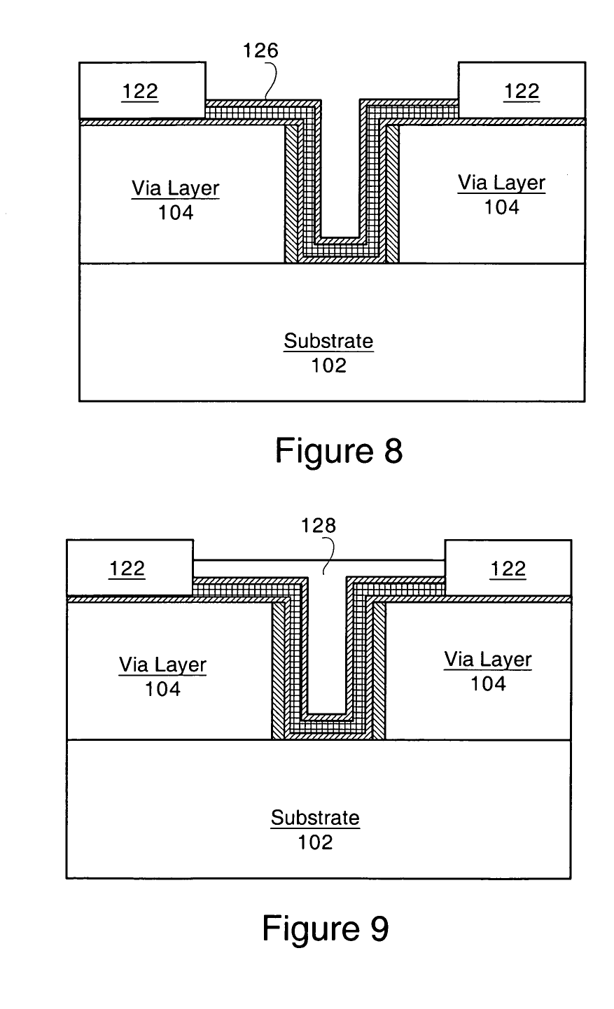

FIG. 8 is a cross sectional side view that illustrates a barrier layer 126 that may be deposited on the conductive layer 124. The barrier layer 126 may be a thin layer of material that may prevent the conductive material from diffusing into dielectric or other material added later. In some embodiments, the barrier layer 126 may act as an adhesion layer in addition to, or in place of, acting as a barrier layer. The barrier layer 126 may allow later-added dielectric or other material to adhere to the conductive layer 124. In one embodiment, the barrier layer 126 may comprise TaN₂. In some embodiments, the barrier layer 126 may comprise one or more of Ta, TaₓN_{y}, SiₓO_{y}, SiₓO_{y}N_{z}, or another material. In some embodiments, the barrier layer 126 may have a thickness of about 1200 angstroms where it is deposited near the top of the via well 110. The barrier layer 126 thickness may decrease further into the via well 110, toward the bottom 116.

FIG. 9 is a cross sectional side view that illustrates a plug material 128 that may fill volume at the center of the via 105 inside the conductive layer 124. In an embodiment, the plug material 128 may comprise a dielectric material, such as an epoxy, or another material. In one embodiment, the plug material 128 may comprise a dielectric oxide material deposited in the center of the via 105 by chemical vapor deposition.

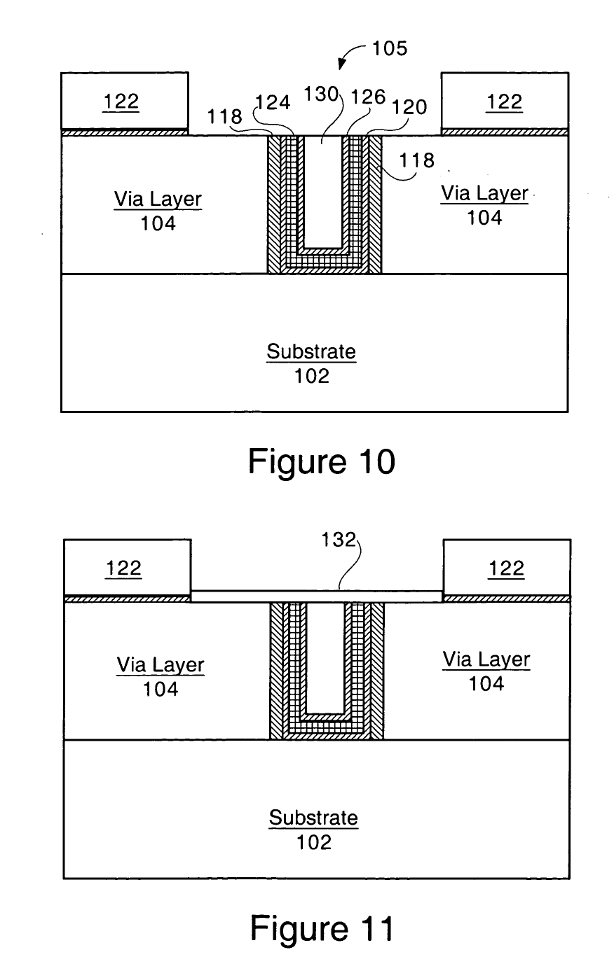

FIG. 10 is a cross sectional side view that illustrates one embodiment of the via 105 after excess material has been removed. In FIG. 10, excess plug material 128, and portions of the insulating layer 118, the barrier layer 120, the conductive layer 124, the barrier layer 126 that were above the top of the via layer 104 have been removed. In various embodiments, this removal of material may be accomplished by methods such as dry etching, wet etching, chemical mechanical planarization (“CMP”), or other methods. This may result in the plug material layer 128 being reduced to a plug 130 that fills the center of the via 105 inside the interior of the conductive layer 124. This may also result in the conductive layer 124 being exposed at the top of the via 105, which may allow the conductive layer 124 to be electrically connected to other structures or devices. For example, when the via 105 has a circular cross section, an annular portion of the conductive layer 124 may be exposed at the top of the via 105 at this stage.

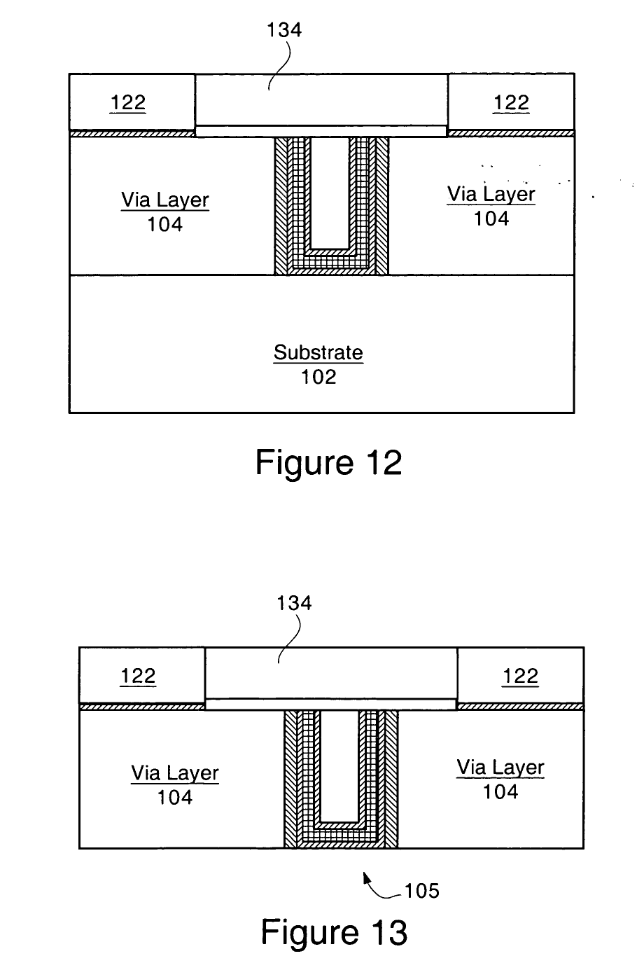

FIG. 11 is a cross sectional side view that illustrates a bulk metal layer 132 that may be deposited on the via 105 and via layer 104 in some embodiments. This bulk metal layer 132 may provide a continuous conductive surface above the via 105 that is electrically connected to the conductive layer 124 of the via 105. FIG. 12 is a cross sectional side view that illustrates a top connective structure 134 that may be on the bulk metal layer 132 in some embodiments. The top connective structure 134 may be a metal interconnect, a landing pad, or another conductive connective structure that is electrically connected to the conductive layer 124 of the via 105, possibly by the bulk metal layer 132 in some embodiments.

FIG. 13 is a cross sectional side view that illustrates an alternate embodiment in which there is no substrate 102; the via 105 extends all the way through the via layer 104. This may be formed, for example, by removing the substrate 102 after forming the via 105, by forming the via 105 without a substrate 102, or by other methods. Removal of the substrate 102 may be accomplished by methods such as etching, chemical mechanical polishing, or other methods.

Other alternate embodiments may also be made. For example some layers may be omitted. One or more of the insulating layer 118, the barrier layers 120 and/or 126, the bulk metal layer 132, the mask 122, the top connective structure 134, or other layers and/or structures may be left out. Additional layers may be added. Layers and structures may be formed in a different order.

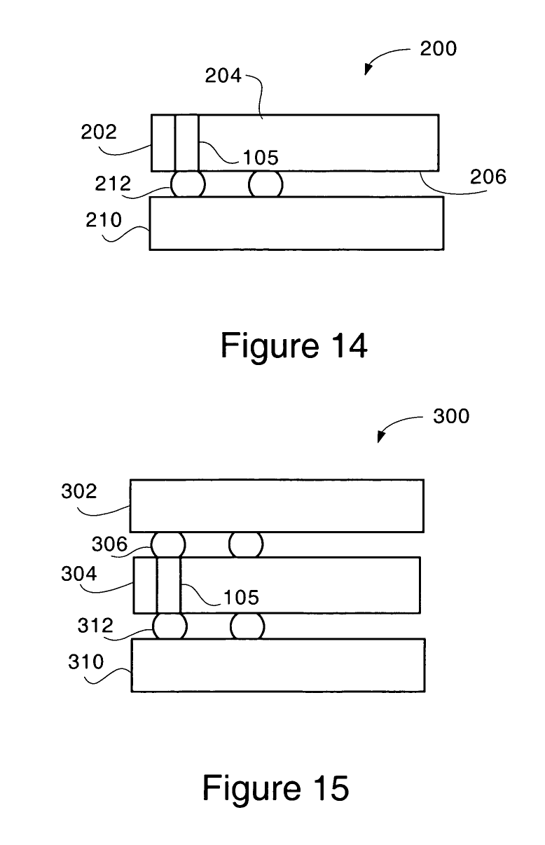

FIG. 14 is a cross sectional side view that illustrates a device 200 that may comprise the via 105. The device 200 may include a substrate 210, such as a package substrate. A microelectronic device die 202, such as a microprocessor, with an active side 206 and a back side 204, may be connected to the package substrate 210 by connectors such as solder balls 212 or other connectors. A high aspect ratio via 105 may provide an electrical connection through the thickness of the die 202 between the active side 206 and the back side 204. The package substrate 210 may in turn be connected to other structures, which may include a structure such as a printed circuit board (PCB). The PCB may in turn be connected to other devices and/or structures to form a computer system, which may include a memory and/or a mass storage unit, and/or other components which may be connected to the PCB. The memory may be any memory, such as random access memory, read only memory, or other memories. The mass storage unit may be a hard disk drive or other mass storage device. The computer system may also include other components such as input/output units, a microprocessor, or other components.

FIG. 15 is a cross sectional side view that illustrates another device 300 that may comprise the via 105. The device 300 may include an interposer 304, such as a silicon interposer. The interposer 304 may be between two electronic devices 302, 310, and connected to the devices 302, 310 by connectors such as solder balls 306, 312 or other connectors. One or both of the electronic devices 302, 310 may comprise active and/or passive electronic devices such as transistors, resistors, capacitors or other devices, and may be, for example, a microprocessor. The high aspect ratio via 105 may extend through the interposer 304 to provide an electrical connection between the sides of the interposer 304, and allow, for example, signals, power, and ground connections to pass through the interposer 304, allowing signals, power, and ground, to be connected between the devices 302, 310 by passing through the interposer 304. Other applications for the high aspect ratio via 105 are also possible.

The foregoing description of the embodiments of the invention has been presented for the purposes of illustration and description. It is not intended to be exhaustive or to limit the invention to the precise forms disclosed. Some layers and steps may be added and other layers or steps added. This description and the claims following include terms, such as left, right, top, bottom, over, under, upper, lower, first, second, etc. that are used for descriptive purposes only and are not to be construed as limiting. The embodiments of a device or article described herein can be manufactured, used, or shipped in a number of positions and orientations. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

1. A method, comprising:
forming a via layer;
patterning the via layer to form a via well through the via layer, the via well having a center;
conformally forming a conductive layer on sides and bottom of the via well, the conductive layer having an interior closer to the via center and an exterior closer to the sides and a bottom of the via well; and
forming a dielectric plug to substantially fill a volume within the interior of the conductive layer.

2. The method of claim 1, wherein the via well has a depth and a width, wherein the depth is at least approximately twice as great as the width.

3. The method of claim 2, wherein the depth is at least approximately three times as great as the width.

4. The method of claim 2, wherein the via well has a depth in a range from about 50 microns to about 250 microns.

5. The method of claim 1, wherein conformally forming a conductive layer comprises:
sputtering a conductive seed layer conformal to the sides and bottom of the via well; and
electroplating a conductive bulk layer on the conductive seed layer.

6. The method of claim 5, wherein the conductive seed layer has a thickness of about 11,000 angstroms or less and the conductive bulk layer has a thickness of about 20 microns or less.

7. The method of claim 1, wherein the conductive layer comprises copper.

8. A device, comprising:
a via layer;
a via well through the via layer, the via well having opposing sides being defined by opposing side walls of the via layer;
a conductive layer on the via well sides and substantially conformal to the via well sides, the conductive layer having an exterior closer to the via layer and an interior further from the via layer; and
a dielectric plug in the interior of the conductive layer to substantially fill a volume within the interior of the conductive layer.

9. The device of claim 8, wherein the conductive layer comprises copper.

10. The device of claim 8, wherein the via well has a depth and a width, wherein the depth is at least approximately twice as great as the width.

11. The device of claim 9, wherein the depth is at least approximately three times as great as the width.

12. The device of claim 9, wherein the via well has a depth in a range from about 50 microns to about 250 microns.

13. The device of claim 12, wherein the conductive layer has a thickness of about 20 microns or less.

14. The device of claim 13, wherein the conductive layer has a thickness of about 10 microns or less.

15. The device of claim 8, further comprising a barrier layer substantially conformal to the via well sides and between the conductive layer and the via well sides.

16. The device of claim 15, wherein the barrier layer comprises Tantalum.

17. The device of claim 8, further comprising:
an insulating layer on the via well sides and between the via layer and the conductive layer;
a barrier layer substantially conformal to the via well sides and between the insulating layer and the conductive layer; and
an adhesion layer on the interior of the conductive layer and between the conductive layer and the dielectric plug.

18. A device, comprising:
a via layer;
a via well through the via layer, the via well having opposing sides being defined by opposing side walls of the via layer, a width, and a depth;
a conductive layer on the via well sides and substantially conformal to the via well sides, the conductive layer having a thickness of less than or equal to one fifth of the width of the via well; and
a dielectric plug in the interior of the conductive layer to substantially fill a volume within an interior of the conductive layer.

19. The device of claim 18, wherein the via well width is in a range from about 50 microns to about 100 microns and the thickness of the conductive layer is in a range from about 8 microns to about 15 microns.

20. A device, comprising:
a via extending through a via layer, the via comprising:
a via well through the via layer, the via well having opposing sides being defined by opposing side walls of the via layer;
a conductive layer on the via well sides and substantially conformal to the via well sides, the conductive layer having an exterior closer to the via layer and an interior further from the via layer; and
a dielectric plug in the interior of the conductive layer to substantially fill a volume within the interior of the conductive layer;
a first device on a first side of the via layer and connected to the via; and
a second device on a second side of the via layer and connected to the via.

21. The device of claim 20, wherein the first device is a microprocessor and the via layer comprises an interposer.
